(19) United States
(12) Patent Application Publication
(10) Pub. No.: US 2003/0118944 A1
(43) Pub. Date: Jun. 26, 2003

(54) Post exposure method for enhancing durability of negative working lithographic plates

(75) Inventors: Harry Copeland, Springfield, MO (US); Charles J. Kramer, Rochester, NY (US); David C. Madoux, Tyler, TX (US); William J. Streeter, Chesterfield, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: Western Litho Plate & Supply Co.

(21) Appl. No.: 10/107,681

(22) Filed: Mar. 27, 2002

Related U.S. Application Data
(60) Provisional application No. 60/341,205, filed on Dec. 17, 2001.

(51) Int. Cl. G03F 7/00

(52) U.S. Cl. 430/302

(57) ABSTRACT

The durability of negative working lithographic plates is enhanced by post-exposure to a wavelength, or a range of wavelengths, effective to promote further addition polymerization and/or cross-linking reactions. Preferably, the electromagnetic energy used for post-exposure comprises a principal wave length not greater than 300 nanometers.

### BACKGROUND OF THE INVENTION

This invention relates to the preparation of lithographic printing plates by computer to plate processing, and more particularly to preparation of a lithographic printing plate by development of a plate in which an image has been prepared by digitally guided laser exposure, followed by post exposure for strengthening and hardening the lithographic image.

In the preparation of lithographic printing plates for high volume applications, e.g., printing of newspapers, computer to plate processing has been introduced as an alternative to the preparation of plates by exposure through a photographic film. In computer to plate (“CTP”) processing, select regions of a negative working light sensitive material are exposed by impingement of a laser beam on the plate in a pattern that is determined, not by an intervening film or filter, but by a digital computer program which positions the laser beam to control its locus of impingement on the plate. Movement of the beam across the plate in accordance with the select pattern produces the desired image in the light sensitive coating. Development of the coating with a suitable solvent or dispersant for the unexposed light sensitive material removes that material from the unexposed regions of the coating, leaving the desired image on the plate for use in printing. Apparatus and method of exposing lithographic plates using CTP technology is described in U.S. Pat. No. 5,934,195, assigned to Western Litho Plate & Supply Co. and incorporated herein by reference for all purposes.

Various light sensitive materials may be used in CTP exposure and development of lithographic printing plates. Preferably so-called photopolymer coatings are used, which comprise an ethylenically unsaturated compound, typically a polymer or oligomer having pendent acrylic moieties, and a photosensitive free radical initiator. Prior to exposure to light, the light sensitive material is subject to removal by a developer. The initiator absorbs visible light or other electromagnetic radiation at certain discrete wavelengths, resulting in the generation of free radicals. The free radicals that are released initiate polymerization and/or cross-linking by addition polymerization via the acrylic moieties resulting in a cross-linked structure that is resistant to the developer and forms an image for printing. The image is generally oleophilic and therefore receptive to printing inks. It can be rendered more oleophilic by further treatment with an oleophilic lacquer or asphaltum. For CTP processing, the light sensitive material further includes a component such as a dye that has an absorption maximum which corresponds to the wave length of the laser (e.g., a wave length within the range of 536 nm to 488 nm for visible laser light). The excited molecule then transfers energy to the free radical initiator material which decomposes to free radicals after the energy transfer. Photopolymerizable light sensitive compositions are described in U.S. Pat. Nos. 5,800,965, 6,153,356 and 6,232,038 of Mitsubishi Chemical Corporation. The light sensitive materials of U.S. Pat. No. 6,232,038 are particularly described as suitable for use in laser processing.

Atmospheric oxygen is reactive with common free radical initiators. If a light sensitive coating comprising an acrylic compound and a free radical initiator is exposed to air at the same time it is exposed to light, oxygen consumes free radicals and inhibits photopolymerization and crosslinking. Oxygen may react with free radicals to yield peroxy radicals which are generally inefficient polymerization initiators, or it may react with growing polymer radicals to yield peroxy radicals that inhibit or terminate chain propagation. Conventionally, photopolymer plates are provided with an oxygen barrier layer over the light sensitive coating to prevent interference of oxygen with the photopolymerization process. The barrier layer is generally subject to removal, either by the developer or before development, e.g., by a simple water spray. Typical photopolymer plates are described in U.S. Pat. No. 5,786,127, which is expressly incorporated herein by reference.

In laser printing, it is desirable to control the time/energy exposure of the light-sensitive coating for optimal dot development. Excessive exposure affects the conformation of image dots in a manner that adversely affects the quality of the lithographic print obtained by use of the exposed plate. Such overexposure is not as significant a problem in conventional exposure processes where dot definition is controlled by a photographic film or mask that positively blocks radiation from reaching non-image areas of the plate.

Unfortunately, in computer to plate laser processing, the optimal time/energy exposure for optimal dot conformation is often less than that required to generate cross-linking sufficient for maximum image hardness and wear resistance. Thus, a plate that is exposed for optimal image quality may not exhibit satisfactory press life. A plate which is exposed sufficiently for maximum wear resistance and press life may not provide prints of the highest quality otherwise achievable with computer to plate technology. A need has remained in the art for a solution to this dilemma, especially in high speed, high volume printing operations such as those involved in the publishing of metropolitan newspapers.

U.S. Pat. No. 4,326,018 describes a method for improving the durability of a conventional subtractive printing plate which comprises both an acrylic light sensitive material and a diazo resin. The plate is not prepared by laser exposure but instead by exposure to ultraviolet light through a photographic negative which serves as a barrier to impingement of light in non-image areas. The patent describes improving the quality of the image by post-curing the plate, which is accomplished by either air baking the developed image, or exposing it to ultraviolet radiation.

U.S. Pat. No. 5,238,747 describes resist images prepared by exposure of a light sensitive coating composition comprising a sulfonium, quaternary ammonium or phosphonium compound, typically a vinylbenzylsulfonium or vinylbenzyltrimethylammonium copolymer, and at least one photo-reactive nucleophile. The resist is described as useful in multiple applications including preparation of filters, membranes, printed circuits and lithographic printing plates. An example in which the resist is developed on a glass slide describes re-exposing the slide to a UV lamp for 10 minutes to harden the film remaining. However, the patent does not discuss post-exposure in the context of lithographic plate preparation. The mechanism of the light-hardening reaction is not explained.

### SUMMARY OF THE INVENTION

Among the several objects of the present invention, therefore, may be noted the provision of an improved process for the preparation and development of negative-working lithographic printing plates; the provision of such a process which is useful in the preparation of printing plates from photopolymer plates; the provision of such a process which is adapted for the preparation of laser exposed plates and especially plates produced using computer to plate technology from digital imaging programs; the provision of such a process which is energy efficient and does not create environmental problems in the workplace or otherwise; the provision of such a process which is effective for the preparation of plates of high quality; and the provision of a process for the preparation of lithographic plates having a long press life, and especially plates suited for high volume printing operations such as the publishing of metropolitan newspapers.

Briefly, therefore, the invention is directed to a process for the preparation of a lithographic printing plate. Regions of a light sensitive coating of a sensitized, negative working lithographic plate are exposed to an electromagnetic beam in a pattern determined by controlling the locus of impingement of the beam on the coating independently of any barrier to the beam, thereby establishing an image in the coating defined by the select exposed regions. The sensitized lithographic plate comprises a support and a light sensitive coating over the support. The light sensitive coating comprising light sensitive material comprises an ethylenically unsaturated compound and a photosensitive free radical initiator effective for initiating addition polymerization and/or cross-linking reactions. The image produced by such exposure is developed by removal of the light sensitive material from the non-exposed regions of the coating. The image is further exposed to electromagnetic radiation comprising a wavelength not greater than about 300 nanometers to promote further addition polymerization and/or cross-linking reactions effective to strengthen the image and increase its press life in a lithographic printing application.

The exposure step in the aforesaid process may comprise further exposing the image to ultraviolet electromagnetic radiation effective: (i) to promote further addition polymerization and/or cross-linking reactions that strengthen said image and increase its press life in a lithographic printing application; and (ii) to produce such cross-linking and image strengthening without consumption of more than 0.3 kW in generation of the radiation during said further exposure.

The invention is further directed to a system for preparing a lithographic printing plate, the plate comprising a support having a light sensitive coating thereon comprising a light sensitive material. The light sensitive material comprises an ethylenically unsaturated compound and a photosensitive free radical initiator effective for initiating addition polymerization and/or cross-linking reactions. The system comprises plate exposure apparatus for exposing select regions of the light sensitive coating of the plate to an electromagnetic beam in a pattern determined by controlling the locus of impingement of the beam on the coating thereby establishing an image in the coating defined by the select regions. The system further comprises a plate developing apparatus for developing the image by removal of the light sensitive material in the non-exposed regions of the coating. The system also includes an image exposure apparatus for exposing the image to electromagnetic radiation at a wavelength not greater than 300 nanometers.

Other objects and features will be in part apparent and in part pointed out hereinafter.

### BRIEF DESCRIPTION OF THE DRAWINGS

FIG. 1 is a plot indicating the laser wavelengths at which an image is generated in various known types of laser processable lithographic plates and the energy required for image generation;

FIG. 2 is a schematic plan view of a system of the invention for use in carrying out the process of the invention, parts being broken away to show details;

FIG. 3 is a schematic side elevational view of the system of FIG. 2;

FIG. 4 is a schematic side elevational view of a plate developing and finishing apparatus of the system of FIG. 3;

FIG. 5 illustrates an apparatus useful in post-exposure of an exposed and developed lithographic plate;

FIG. 6 is a view similar to FIG. 2 showing a second embodiment of a system of the present invention;

FIG. 7 is a schematic side elevational view of a housing incorporating development and finishing apparatus and post-exposure apparatus of the present invention;

FIG. 7A is a variation of FIG. 7;

FIG. 8 is an illustration of the profile of an image dot of an undesired conformation as prepared by laser exposure of a photopolymer plate due to overexposure of the plate; and

FIG. 9 is an illustration comparable to FIG. 8, but showing an image dot having a desired conformation.

Corresponding reference characters indicate corresponding parts throughout the drawings.

### DESCRIPTION OF THE PREFERRED EMBODIMENTS

In accordance with the invention, the image areas of an exposed and developed lithographic plate, especially a laser imaged plate, are substantially strengthened, and press life substantially extended. It has been discovered that, after the image has been developed, the material in the image area can be hardened and strengthened by further exposure to electromagnetic radiation, and that this can be accomplished without deterioration of dot conformation. The deterioration observed on overexposure before development is perhaps related to the presence of unexposed light sensitive material in regions immediately outside the locus of the beam, e.g., in regions surrounding the dot. Once the unexposed light sensitive material has been removed by development, the image can be subjected to further exposure without effect on the dot. Consequently, in the initial exposure process, the plate can be exposed only to that quantum of electromagnetic energy sufficient for optimal development of the image and dot configurations. Thereafter the plate is further exposed to enhance the durability of the image, without sacrifice of image quality.

Plates that are subject to enhancement by the process of the invention particularly include developed plates that are produced from so-called photopolymer sensitized plates, i.e., sensitized plates having a light sensitive coating comprising an ethylenically unsaturated compound and a free radical initiator from which free radicals are generated upon exposure of the light sensitive coating to light or other electromagnetic radiation at a wavelength absorbed by the initiator. Preferably, the ethylenically unsaturated compound is an acrylic monomer, or a polymer or oligomer comprising a pendent acrylic moiety. As described above and more particularly in U.S. Pat. No. 5,786,127, monomers useful as the ethylenically unsaturated compound include acrylates such as ethylene glycol diacrylate, triethylene glycol diacrylate, trimethylolpropane triacrylate, trimethylolethane triacrylate, pentaerythritol diacrylate, pentaerythritol triacrylate, pentaerythritol tetracrylate, dipentaerythritol tetracrylate, dipentaerythritol pentacrylate, dipentaerythritol hexacrylate, glycerol acrylate, hydroquinone diacrylate, hydroquinone dimethacrylate, resorcinol diacrylate, resorcinol dimethacrylate, pyrogallol triacrylate, and the corresponding methacrylates, itaconates, crotonates and maleates.

The proportion of ethylenically unsaturated compound in the photosensitive composition is usually from about 5 to about 90% by weight of the photosensitive layer, preferably from about 10% to about 50% by weight. Various conventional free radical photo initiators may be used. For example, benzoin, benzoin alkyl ether, benzophenone, anthraquinone, benzyl, Michler's ketone or a complex system of biimidiazole and Michler's ketone. All of these are effective for the post-curing step as described below. For use in the methods of the invention comprising laser development of the image, the photosensitive composition preferably comprises at least one initiator, e.g., biimidazole, that is subject to excitation by transfer of energy from a dye compound or other molecule that has an absorption maximum at the wavelength of incident light from a laser used for creating the image, but can also function by direct irradiation from a conventional uv energy source. A particularly preferred photo initiator is bis(η-5-2,4-cyclopentadien-1-yl)-bis(2,6-difluoro-3-(1H-pyrrol-1-yl)-phenyl)titanium:

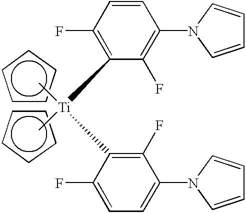

which is sold under the trade designation IRGACURE® 784 by Ciba Specialty Chemicals. The proportion of free radical initiator in the light sensitive coating is usually between about 0.1 and about 20% by weight of the coating, preferably from about 0.2 to about 10% by weight.

Preferably, the photosensitive layer of a CTP plate further contains a component such as a dye which has a maximum in its absorption spectrum at the wavelength of incident light from the laser that is used to establish the image. Only a very minor proportion of dye compound is needed. Excitation of the dye transfers energy to the free radical initiator, resulting in generation of free radicals which promote addition polymerization of the addition polymerizable compound.

The photosensitive layer may also contain an organic polymer binder for purposes of modifying the layer or for improving its physical properties after photo curing. Selection of the binder depends on the purpose it is intended to serve. It may, for example, be chosen to provide compatibility, film forming properties, enhanced susceptibility to development or adhesive properties. For improvement of developing properties, the binder may, for example, be an acrylic acid copolymer, a methacrylic acid copolymer, itaconic acid copolymer, a partially esterified maleic acid copolymer, an acidic cellulose modified product having a carboxyl group in its side chains, a polyethylene oxide or polyvinyl pyrrolidone. For improvement of coating film strength and adhesion properties, the light sensitive coating may contain, for example, a polyether of epichlorohydrin and bisphenol A, a soluble nylon, a polyalkyl methacrylate or polyalkyl acrylate such as polymethyl methacrylate, a copolymer of an alkyl methacrylate with acrylonitrile, acrylic acid, methacrylic acid, vinyl chloride, vinylidene chloride or styrene, a copolymer of acrylonitrile with vinyl chloride or vinylidene chloride, a copolymer of vinyl acetate with vinylidene chloride, a chlorinated polyolefin or vinyl chloride, polyvinyl acetate, a copolymer of acrylonitrile and styrene, a copolymer of acrylonitrile with butadiene and styrene, a polyvinyl alkyl ether, a polyvinyl alkyl ketone, a polystyrene, a polyamide, a polyurethane, a polyethylene terephthalate isophthalate, acetylcelluose or polyvinvyl butyral. Such a binder may be incorporated in a proportion within a range of not more than 500% by weight, preferably not more than 200% by weight relative to the ethylenic compound. As described in U.S. Pat. No. 5,786,127, the light sensitive coating may also include dyes, pigments, thermal polymerization inhibitors, coating property improving agents, plasticizers and stabilizers.

Ethylenically unsaturated polymers and binders useful in the process of the present invention further include those described in U.S. Pat. Nos. 5,800,965, 6,153,356 and 6,232,038, each of which is expressly incorporated herein by reference.

The addition-polymerizable monomers described in U.S. Pat. No. 5,800,965 contain a specific monomer which is a phosphoric acid ester compound (A-1) having at least one (meth)acryloyl group and/or a compound (A-2) of the formula:

CH₂═C(R¹)—C(O)—(X—O)ₘ—H

where R¹ is H or methyl, X is C₁₋₆ alkylene which may be branched and may be substituted by halogen, and m is an integer ≧2. The polymer binder is a compound having at least a part of the carboxyl groups reacted with an alicyclic epoxy group-containing unsaturated compound. Exemplary addition polymerizable compounds disclosed in U.S. Pat. No. 5,800,965 include ethylene glycol methacrylate phosphate:

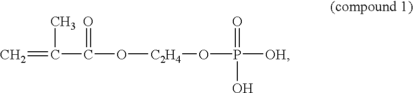

di(methacryloyloxyethyl)phosphate:

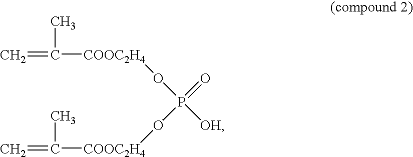

bis[(triacrylyloxymethyl) ethyl ester of ethylene-1,2-dicarbamic acid:

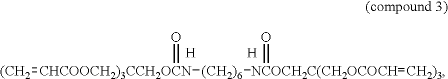

and the bis(acrylyl) ester of the bis(polyethylene glycol)ester of bisphenol A:

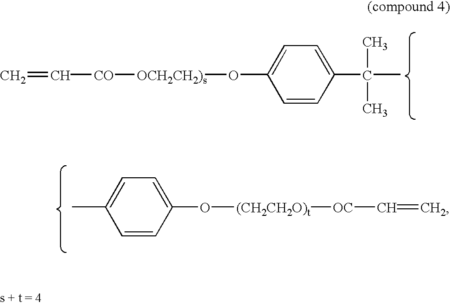

and the methacrylyl monoester of polyethylene glycol.

The lithographic plate of U.S. Pat. No. 5,800,965 preferably comprises a grained and sulfuric acid anodized aluminum support.

U.S. Pat. No. 6,153,356 includes an exemplary list of ethylenically unsaturated monomers (col. 3, lines 3 to 43), as well as various classes of suitable addition polymerizable or cross-linkable polymers that are useful in preparing lithographic plates that may be processed in accordance with the present invention. Such addition polymerizable or cross-linkable polymers include: (1) polyesters obtained by condensation of an unsaturated dicarboxylic acid and a dihydroxy compound; (2) polyamides obtained by condensation of an unsaturated dicarboxylic acid and a diamine compound; (3) polyesters obtained by polycondensation reactions of itaconic acid, ethylidenemalonic acid or propylidenesuccinic acid with a dihydroxy compound; (4) polyamides obtained by polycondensation reactions of itaconic acid, ethylidenemalonic acid or propylidenesuccinic acid with a diamine compound; (5) polymers obtained by a reaction of an unsaturated carboxylic acid with a polymer having reactive functional groups such as hydroxyl groups or halogenated methyl groups in its side chain, such as a polyvinyl alcohol, a poly(2-hydroxyethyl methacrylate) or a polyepichlorohydrin. Specific addition polymerizable monomers exemplified in U.S. Pat. No. 6,153,356 include a methyl methacrylate/methacrylic acid copolymer (90/10 molar ratio), trimethylolpropane triacrylate, methyl methacrylate/isobutyl methacrylate/isobutyl acrylate/methacrylic acid in a 35/20/10/35 ratio) and (a-methyl)styrene/acrylic acid.

U.S. Pat. No. 6,232,038 is expressly directed to lithographic plates that are subject to laser processing. This patent describes a large number of ethylenically unsaturated compounds that are also useful in the present invention, including ester acrylates (col. 3, lines 17-33), epoxy acrylates (col. 3, line 34 to col. 4, line 23) and urethane acrylates (col. 4, line 23 et seq.) Among the specifically exemplified light sensitive materials is a mixture of benzyl methacrylate/methacrylic acid and dipentaerythritol hexaacrylate, styrene/acrylic acid, urethane methacrylate, and ethylene glycol diacrylate.

Over the light sensitive coating the sensitized lithographic plate also preferably comprises a protective coating which serves as a barrier against diffusion of atmospheric oxygen into the light sensitive coating. As described in U.S. Pat. No. 5,786,127 such protective coatings typically comprise polyvinyl alcohol and may also include components such as polyvinyl pyrrolidone, partially hydrolyzed maleic anhydride, partially hydrolyzed vinyl acetate, and copolymers of hydrolyzed vinyl acetate and vinyl pyrrolidone, etc.

Other polymer plates and light sensitive materials useful in preparing lithographic printing plates according to this invention include those described in U.S. Pat. Nos. 5,723,260, 5,260,167, each of which is incorporated herein by reference.

As described in the aforementioned U.S. Pat. No. 5,934,195, select regions of the sensitized plate are initially exposed to a laser or other electromagnetic beam by moving the beam across the plate or otherwise positioning the beam to expose the plate in a desired pattern corresponding to the image to be produced. The pattern is determined primarily or entirely by controlling the locus of impingement of the beam on the coating, independently of any barrier to the beam. The laser or other electromagnetic beam is preferably positioned under the guidance of a computer that is digitally programmed to create the image in the desired pattern. Such exposure process is generally referred to in the art as “computer to plate” technology or “CTP.” No filter or mask intervening between the light source and the plate is necessary to the creation of the image. It will be understood that, if desired, a filter, film or mask may be used to bar access of light to some regions of the light sensitive coating, but the aforesaid select regions are exposed to radiation by control of the direction of the electromagnetic beam, independently of any light barrier. Among the commercially available photopolymer plates that may be used in the process of the invention are those sold by Western Litho Plate & Supply Co. under the trade designations “LT-G” for exposure at a wavelength of 1064 nm (infrared), “LT-2” and “LT-N″ for exposure at 830 nm (infrared), “LY” for exposure at 532 nm (visible), “LA” for exposure at 488 nm (visible), and “LV-1” for exposure at 410 nm (visible).

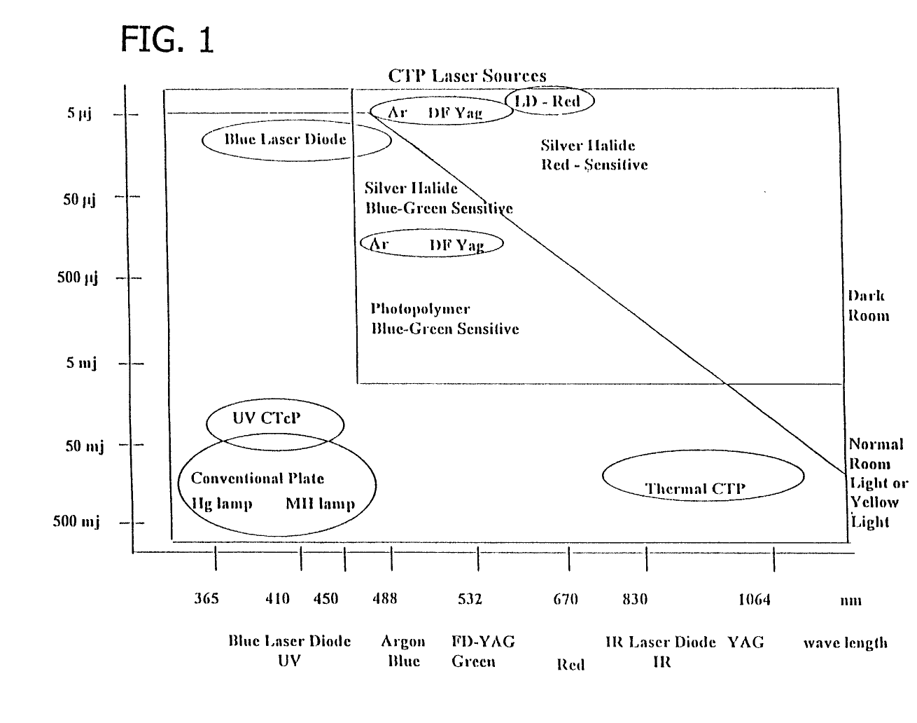

FIG. 1 illustrates the energy requirements for exposure of various sensitized plates. Generally, plates devised for laser exposure, especially those provided with an oxygen barrier layer, require much less energy for image formation than do conventional UV-exposed diazo plates. Preferably, plates prepared by laser exposure in computer to plate processing are substantially devoid of any light sensitive coating containing a diazo resin in a proportion sufficient for the formation of an image.

After exposure, the image is developed. Ordinarily, this is accomplished by applying a liquid developer to the plate which functions as a solvent or dispersant for unexposed light sensitive material. The developer may typically include a polar organic solvent such as cyclohexanone, and may further comprise an aqueous base. After development, the plate is subject to finishing treatment and then dried. Finishing typically includes the application of a starch, dextran or hydrophilic gum, such as gum arabic to the non-image areas of the plate, and optionally an oleophilic material, such as asphaltum, to the image areas. Phosphoric acid or similar material may also be applied to enhance the hydrophilicity of the non-image areas.

In accordance with the process of the invention, the developed and finished plate is subjected to a post curing procedure in which the image is further exposed to electromagnetic radiation. It has been demonstrated that the exposed and developed image contains residual free radical initiator in proportions effective to promote further additional polymerization and/or cross-linking reactions. Post-curing is conducted within a range of wavelengths that includes a wavelength at which the initiator (or dye molecule) absorbs energy sufficient to promote further such reactions that are effective to strengthen the image and increase its press life in a lithographic printing application. Generally, the initiator exhibits substantial absorbance over at least a modest range of wavelengths (and an inverse range of frequencies) surrounding a peak or principal wavelength of maximum absorbance, electromagnetic radiation across such range being found effective to promote the cross-linking reaction. Absorbance of the free radical initiator is preferably at least about 0.4, preferably at least about 0.6 at the principal wavelength. Where the energy emitted by the electromagnetic source is not concentrated in a narrow frequency range, the integrated average of the power absorbed by the initiator (i.e., the product of the absorbance at a particular wavelength x the electromagnetic power output of the source at the same wavelength) over the electromagnetic spectrum emitted by the source should be sufficient to meet the power requirements as specified hereinbelow.

Generally, the unit energy requirements for post exposure are relatively high because the oxygen barrier layer has been removed in development of the plate. Thus, atmospheric oxygen can penetrate the image, and react with and destroy free radicals remaining in the image, or otherwise inhibit further photoreaction as described hereinabove. Post-curing can be conducted by exposure to electromagnetic energy at an absorption maximum of the free radical initiator, or at an absorption maximum of another molecule, such as a dye, which transfers energy to the initiator. To effect further cross-linking with the diminished supply of active free radicals, the energy required is substantially in excess of that indicated in FIG. 1 for an undeveloped laser plate in which the oxygen barrier layer has remained intact.

However, in accordance with the invention, it has further been discovered that post-curing can be conducted with high energy efficiency if the initiator or the dye molecule (or the photopolymer itself) is sensitive to electromagnetic radiation in the ultraviolet range, so that the radiation actually used for further exposure of the image can be in the ultraviolet range. It is especially advantageous if the radiation used for post-exposure has a wavelength shorter than about 300 nm. Although this discovery does not prevent the consumption of free radicals by reaction with atmospheric oxygen, it nonetheless makes effective post-curing feasible at reasonable rates of energy consumption despite the effect of oxygen inhibition. For many free radical initiators, it is believed that the absorbance spectrum widens at such short wavelengths, so that the absorption maxima of the dye component becomes generally less significant than it might be in selecting a post exposure wave length above 300 nm. Thus, for example, highly satisfactory post-curing can be realized where the free radical initiator comprises the titanium complex sold under the trade designation IRGACURE® 784 by Ciba Specialty Chemicals, and electromagnetic energy is impinged at a preferred wavelength in the range of 240 to 270 nm. IRGACURE® 784 exhibits a substantial absorbance over at least a modest range of wavelengths within the 240 to 270 nm range. In fact, it further appears that this and other common free radical initiators may exhibit substantial absorbance across that entire range of 240 to 270 nm and perhaps substantially across the range of 200 to 300 nm.

Post-curing of laser imaged photopolymer plates can also be realized at longer wavelengths, in the near ultraviolet or visible range. However, shorter wavelengths are strongly preferred. Advantageously, it has been found that the energy requirements for post-curing appear to be much lower at wavelengths shorter than 300 nm than for significantly longer wavelengths. For example, in post-curing at a wavelength in the range of 340 to 370 nm, the energy requirement for post-curing is preferably at least 400 mj/cm² and more preferably about 500 mj/cm², necessitating a power input to the plate surface of about 250 mW/cm² (at 500 mj/cm²) to obtain reasonable productivity. Such energy demand in turn requires the use of metal halide or Hg vapor lamps that are relatively inefficient and therefore consume power at rate of up to 10 kW. The result is not only high energy consumption but also enormous heat generation, which creates an uncomfortable working environment unless high capacity air conditioning is provided, with the further energy consumption which that entails.

However, where post-exposure is at a wavelength or range of wavelengths within the range of 240 to 270 nm, energy demand is only about 150 to 250 mj/cm², even in the absence of the oxygen barrier. This allows reasonable productivity with a lamp power onput to the plate in the range of about 9 to about 15 watts/cm². Thus, in the latter range of wavelengths, the requisite power requirement can conveniently and advantageously be met by a biocidal low-pressure mercury vapor lamp (e.g. at 254 nm). It has been found that energy consumption of a post-exposure station using this lamp is 0.3 kW. A standard HVAC system for a plate preparation and processing operation is effective to maintain comfortable temperatures in the range of 220 to 30° C.

Post-exposure in accordance with the process of the invention does not require any thermal treatment, such as the baking process that is commonly used for diazo plates in the prior art. Radiation post-curing proceeds rapidly and satisfactorily at temperatures that are convenient and comfortable for operations personnel, e.g., in the aforesaid 220 to 30° C. range.

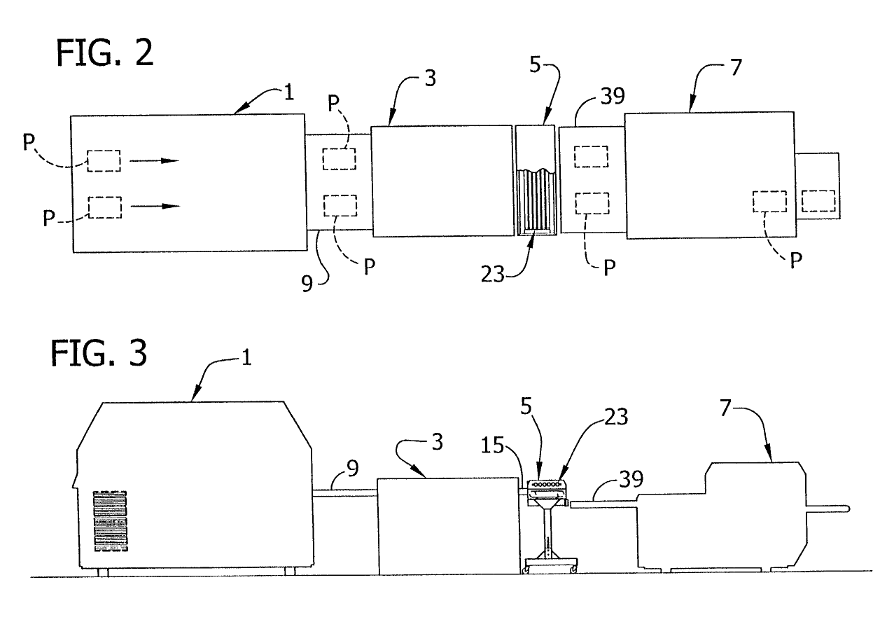

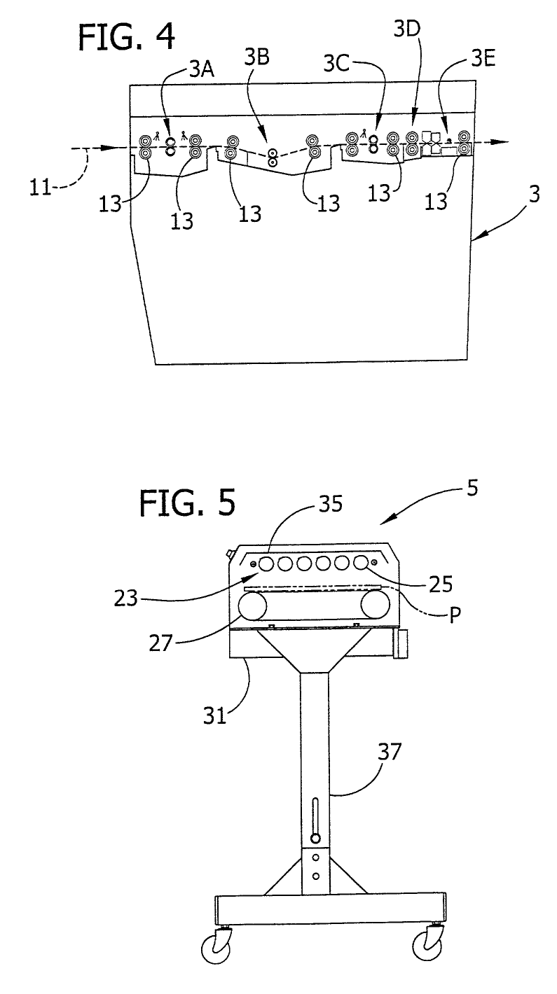

Illustrated in FIGS. 2-5 is a plate processing system for processing photosensitive plates P to make printing plates. The system comprises a digital laser plate exposure apparatus 1, a plate developing and finishing apparatus 3, an image exposure (hereinafter “post-exposure”) apparatus 5, and a plate bending apparatus 7. Plates P delivered to apparatus 1 are exposed by a laser imaging system, such as the system described in U.S. Pat. No. 5,934,195. In this system, a laser beam is moved over the plate under the guidance of a computer (not shown) to produce a desired image, the computer being programmed to create the image as described in the aforesaid patent. The exposed plates are continuously or intermittently delivered from apparatus 1 to apparatus 3 by an exposed plate conveyor 9. As shown in FIG. 4, apparatus 3 comprises a processor having a section 3A subjecting each plate to a pre-wash, a section 3B for development of the plate, a section 3C for washing the plate, a section 3D for gumming, etching and application of an oleophilic coating over the image of the developed plate, and a drying section 3E where the gummed and finished plate is dried. The plates are moved along a path 11 through apparatus 3 by suitable means, such as a series of rollers 13. The processor 3 having sections 3A-3E may be of any conventional design suitable for treatment of CTP plates, as will be understood by those skilled in the art. One such processor is “Diamond Plate 92 Processor” sold by Western Litho Plate & Supply Co. of St. Louis, Mo. Developed and finished plates are delivered from development and finishing apparatus 3 to post-exposure apparatus 5 via another conveyor 15 the operation of which is preferably synchronized with the operation of apparatus 3 and 5 to provide for the feed of plates into apparatus 5 at a substantially constant rate. Apparatus 1, 3, 5 and 7 may be adapted for handling a single line of plates P, or two or more parallel lines of plates P, as shown in the drawings.

In the post-exposure apparatus 5, the plates P are passed continuously or intermittently under an electromagnetic energy source 23. As shown in FIG. 5, this source is preferably a bank of tubular fluorescent lamps 25 operating at a principal wavelength in the range of about 200 to about 300 nm. The lamps 25 are arranged in number and location to radiate energy of the desired wavelength over a field within the post-exposure apparatus 5 through which the previously exposed and developed plate is moved. Conveniently, the plate is spaced between about 1-12 cm, and more preferably about 5-6 cm, from the light source 23. In order to produce plates at a rate of about 150 to 250 per hour, and to synchronize the transfer of plates through the post-exposure apparatus 5 with the movement of plates through initial exposure apparatus 1 and developing apparatus 3, the plates are passed through the post-exposure apparatus 5 at an average rate of at least about 2 feet per minute (fpm) typically between about 2 fpm and about 6 fpm, more preferably between about 3 fpm and about 5 fpm, optimally about 4 fpm. The lamps 25 are typically between about 117 and about 122 cm length, i.e., comparable to the greatest dimension of the plate; and the time of exposure is between about 15 and about 45 seconds, preferably between about 18 and about 30 seconds, most preferably between about 20 and about 23 seconds. The power output of the electromagnetic power source should be sufficient to deliver a total of 150 to 250 mj/cm² of energy to the image at the desired wavelength. Because of the high electrical energy conversion efficiency of the fluorescent lamps, the energy consumption of the lamps is not greater than about 0.3 kw for the station as whole. Temperature within the post-exposure station is preferably not substantially more than ambient, i.e., not more than about 10° C. above ambient (22° C.-30° C.).

As illustrated in FIGS. 2-4, after the developed plate is subjected to gumming and other plate finishing operations, it may be dried in the drying section 3E of apparatus 3 prior to post exposure in apparatus 5. Drying is conveniently effected by passage of air over the wet plate at substantially ambient or slightly elevated temperature, e.g., between about 45° C. and about 55° C. However, in accordance with the invention, it has been discovered that post-exposure can be conducted while the plate is still wet. Advantageously, drying and post-exposure can be conducted simultaneously in a single plate processing station, with resultant economies in capital cost, maintenance expense, and space requirements, as will be described hereinafter.

FIG. 5 illustrates apparatus 5 for subjecting photopolymer plates to a post-exposure process intended to strengthen the image areas of the plate and thus provide for a longer plate run length. In this embodiment, apparatus 5 comprises a conveyor 27 (e.g., an endless belt) for receiving developed and finished plates P from apparatus 3 and conveying them in a forward direction (from left to right in FIG. 5). The conveyor 27 is disposed within a housing 31 which supports the aforementioned electromagnetic energy source 23 which, as previously explained, is preferably a series of low-pressure mercury vapor lamps 25 mounted within the housing to extend generally transversely with respect to the direction of plate travel through the housing. In the particular embodiment shown in FIG. 5, six lamps 25 are used, but this number may vary from one lamp to many lamps so long as the required energy is delivered to the plates, as noted above. A reflector 35 is preferably mounted in the housing immediately above the lamps 25 to direct energy toward the plates passing therebelow. The lamps may be mounted in the housing by any suitable means, e.g., brackets, with suitable ballasts and switching being provided to energize and de-energize the lamps as needed. Since the lamps 25 preferably operate to emit UV-light in the range of about 200-300 nm, which can be harmful to the human eye, precautions should be taken to inhibit the escape of significant radiation from the housing 31. For example, flexible curtains may be used to close the forward and rearward ends of the housing. The conveyor 27 and housing 31 are supported at the appropriate elevation by a suitable stand or pedestal 37. Plates exiting the housing 21 may be transported to the bending apparatus 7 by a conveyor 39, or by hand. Suitable bending apparatus is described in U.S. Pat. No. 5,454,247, assigned to Western Litho Plate & Supply Co. and incorporated herein by reference. Other bending apparatus is also suitable.

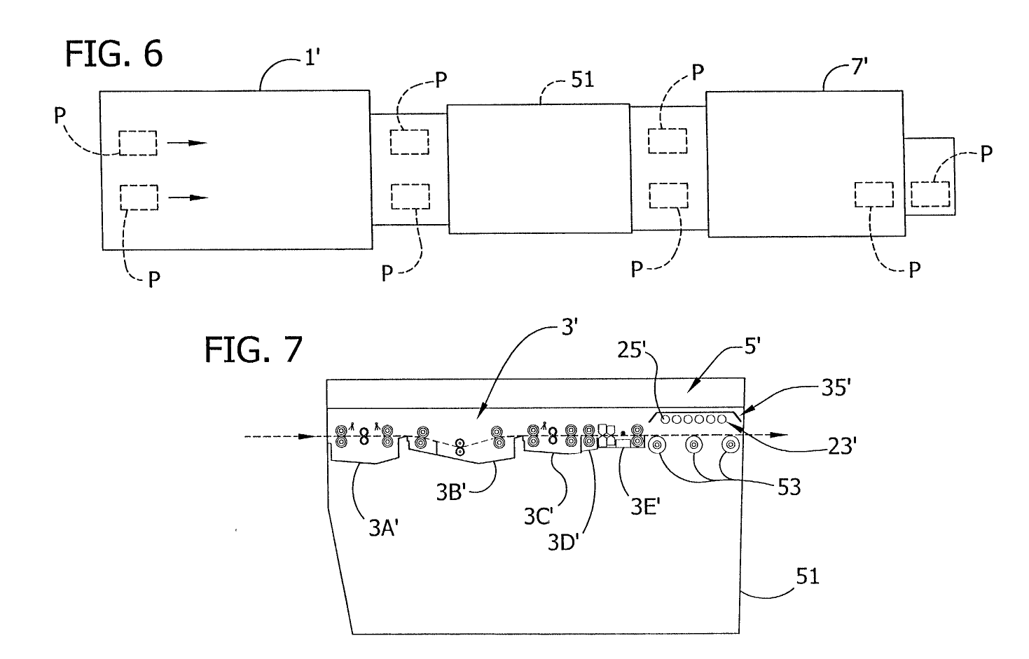

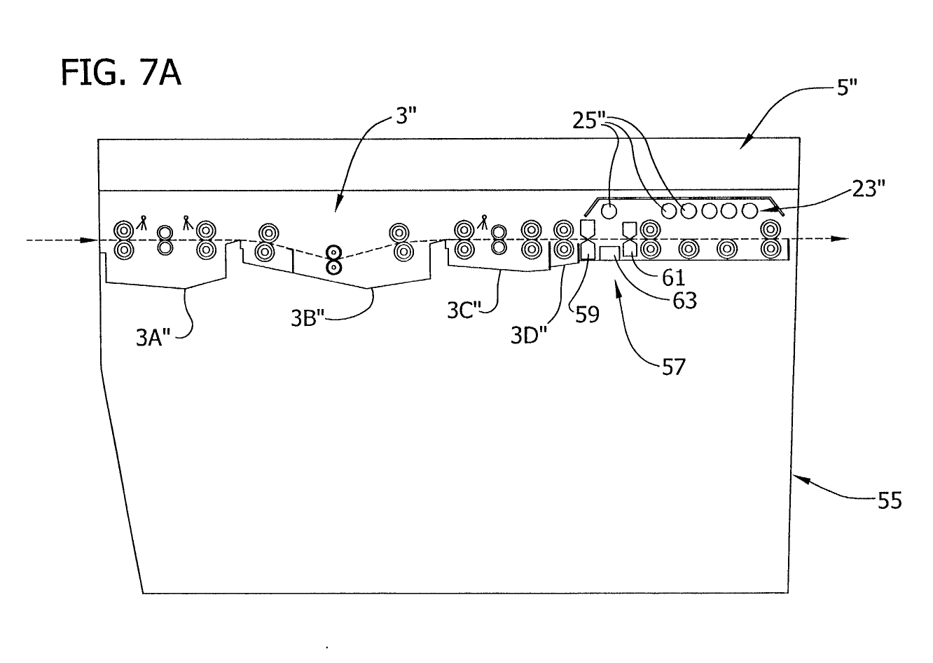

FIGS. 6 and 7 illustrate an alternative plate processing system of the present invention. (This alternative system is similar to the system of FIGS. 2-5, so for the sake of convenience similar equipment is identified by the same reference numeral but with the addition of a prime (′) designation.) The system of FIGS. 6 and 7 comprises a laser exposure apparatus 1′ and a plate bending apparatus 7′ identical to that described above. However, in this embodiment apparatus 3′ for developing and finishing the plates and apparatus 5′ for post-exposing the plates are combined in a single housing 51. Apparatus 5′ is similar to the post-exposure apparatus 5 previously described, comprising a conveyor (e.g., a series of positively driven rollers 53) for receiving developed and finished plates from the drying section 3E′ of apparatus 3′, and a source 23′ of electromagnetic energy, preferably a bank of low pressure mercury vapor lamps 25′ (e.g., six lamps) mounted within the housing and extending generally transversely with respect to the direction of plates. As in the first embodiment, a reflector 35′ is preferably mounted in the housing 51 immediately above the lamps to direct energy toward the plates passing therebelow. The lamps 15′ are mounted in the housing by any means, e.g., brackets. Suitable ballasts and switching are provided to energize and de-energize the lamps as needed.

FIG. 7A illustrates a variation of the apparatus shown in FIG. 7, similar components being identified by the same reference numerals but with the addition of a double-prime (″) designation. In this embodiment, drying and post-exposure of the plates is conducted simultaneously in a single plate processing station, generally designated 55. To this end, drying apparatus 57 is positioned between adjacent post-exposure lamps 25″. This apparatus may comprise, for example, spaced-apart sets of conventional air knives 59, 61, and a plate support 63 between the two sets of knives.

Plates that are processed in accordance with the process of the present invention have been shown to consistently exhibit a press life at least 15% longer than plates that are initially exposed, developed and finished in the same manner but not subjected to post-exposure. For example, in newspaper applications, the plates have been demonstrated to reliably provide runs of at least 250,000, more typically greater than 500,000 impressions, compared to less than 200,000 impressions for plates without post-exposure under the same press conditions.

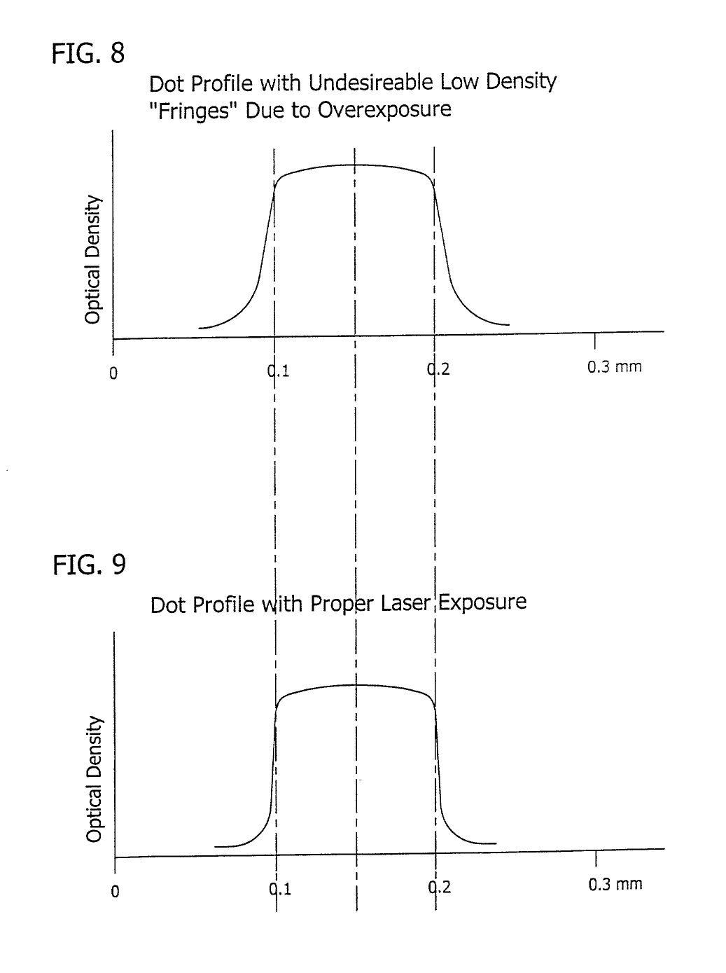

Plates prepared in accordance with the invention may also be subjected to optimal initial exposure for maximum print quality. FIG. 8 is an illustration of the profile (cross-section) of a dot that has been overexposed in an attempt to achieve maximum image durability during initial exposure. It may be seen that a excessive shoulder has been generated on the periphery of the dot, which attracts ink and detracts from image definition. FIG. 9, by comparison, is an illustration of a the cross-section of a dot which has been subjected to optimal exposure. Although this dot also has a shoulder, it is not excessive, and not of a conformation which attracts ink in a manner which detracts from image quality. The conformation of the dot is a function of the extent of exposure. Dot quality improves up to a certain degree of exposure, and then begins to deteriorate, i.e., there is an optimal degree of exposure for image quality. Unfortunately, as noted above, the degree of exposure optimal for image quality is often not sufficient for maximum image durability and run length. In accordance with the method of the invention, the plate can be initially exposed only to the extent of optimal image development, after which it is developed, finished and then post-exposed to achieve the durability necessary for the service contemplated for the plate.

The following examples illustrate the invention.

### EXAMPLE 1

A solid image (1.5″×1.5″) was produced by exposure of a 4″×4″ photopolymer sensitized lithographic plate sold by Western Litho Plate & Supply Co. under the trade designation “Diamond LY-5.” The plate was exposed through a red filter and an interfering glass filter (532 nm, Edmund Scientific Company) at 22 to 28° C. to a 1000 watt metal halide lamp provided by nuArc Company, Inc. Total exposure was 26 mj/cm².

The image was developed in a plate processor (apparatus 3 described above) sold under the trade designation “DiamondPlate 92 Processor” by Western Litho Plate & Supply Co., using a liquid developer sold under the trade designation “DiamondPlate Laser Developer” also by Western Litho Plate & Supply Co. The plate was moved through the processor at a rate of 4 ft/min. The temperature of the developer in the processor was 86F.

After development and drying, the plate was passed on a conveyor through a post-exposure unit obtained from American Ultraviolet Company containing a medium pressure mercury vapor lamp (360 nm; 3811 in length; 125 watts/in) with cold mirror and IR plate. Dimensions of the conveyor were width 40″, length 30″. The distance from the lamp to conveyor supporting the plate was 4.5″. Speed of the conveyor through the post-exposure station was 5 ft/min.

A second plate was processed in the same manner as the first plate except that the conveyor was moved through the post-exposure unit at a speed of 15 ft/min.

A third plate was prepared, exposed and developed in the same manner as the first plate, and then subjected to post-exposure in an exposure unit similar to apparatus 5 described above containing four 50-watt low vapor Hg lamps sold under the trade designation “Ster-L-Ray” G48T6L″ by Atlantic Ultraviolet Company (254 nm; 48″ length). The plate was passed through the post-exposure unit on a conveyor (e.g., 27) at a rate of 3 ft/min. Dimensions of the field of exposure in the post-exposure unit were width 52″, length 18″.

A fourth plate was processed in a manner identical to the third plate except that the conveyor speed through the post-exposure unit was 6 ft/min.

A fifth plate was processed in a manner essentially identical to the third plate except that post-exposure was by a 365 nm metal halide lamp having a rating of 6000 watts and sold under the trade designation FT40APR by nuArc Company. Total post-exposure electromagnetic energy was 300 mj/cm² image.

A sixth plate was prepared in the same manner as the other plates but subjected to no post-exposure.

Each test plate was immersed for three minutes in a liquid developer sold under the trade designation “Polychem XS-790” by U.S. Polychemical Corp. After removal from the developer, each of the specimens was thoroughly washed with tap water. Damaged resist was then wiped off with a sponge, and the optical density (cyan) of each plate was checked using a Gretag D-194 densitometer. Results of the tests of this Example are set forth in Table 1.

TABLE 1

| | Optical Density | Resist Retention |
|---|---|---|
| Test Plates | (Cyan)-(1) | %-(2) |
| 1 | 1.45 | 93% |
| 2 | 1.44 | 92% |
| 3 | 1.34 | 81% |
| 4 | 1.28 | 74% |
| 5 | 1.27 | 73% |
| 6 | 0.64 | 2% |

Optical Density of Background (No Image Area)-(3): 0.62
Optical Density of Original Solid Image-(4): 1.51
Resist Retention % was calculated by the following equation.
(2) = {(1) − (3)}/{(4) − (3)}*100

The percent resist retention of the plates is indicative of the relative run lengths of the plates. It will be observed from Table 1, therefore, that the expected run lengths of test plates 3 and 4, subjected to a post-exposure process in accordance with the present invention using low-energy UV light at 254 nm, compare very favorably to test plates 1, 2 and 5 which were subjected to post-exposure at higher wavelengths and energy.

### EXAMPLE 2

A solid image (1.5″×1.5″) was produced on a 4″×4″ Diamond LY-5 plate substantially in the manner described in Example 1.

The image was hand developed in a tray using DiamondPlate Laser Developer as provided by Western Litho Plate & Supply Co. Dwelling time during development was 79 seconds and the temperature was 79° F.

After development and drying, the plate was passed through a post-exposure unit similar to apparatus 5 described above containing six 50-watt Hg vapor lamps (254 nm) sold under the trade designation “Ster-L-Ray” G48T6L” by Atlantic Ultraviolet Company. Dimensions of the field of exposure in the exposure unit were width 52″, length 18″. The plate was passed through the post-exposure unit on a conveyor moving at a speed of 2 ft/min.

A second plate was processed in a manner identical to the first plate, except that the second plate was not dried before introduction into the post-exposure unit, but was instead post-exposed in a wet condition.

A third plate was processed in a manner identical to the first plate, except that the third plate was moved through the post-exposure unit at a rate of 4 ft/min.

A fourth plate was processed in a wet condition the same manner as the second plate, except that the fourth plate was moved through the post-exposure unit at a speed of 4 ft/min.

A fifth plate was processed in the same manner as the first and third plates except that the fifth plate was moved through the post-exposure unit at a speed of 6 ft/min.

A sixth plate was processed in a wet condition in the same manner as the second and fourth plates, except that the sixth plate was passed through the post-exposure unit at a speed of 6 ft/min.

A seventh plate was not subjected to any form of post exposure.

Each of the plates was thereafter immersed for 24 hours in a liquid developer sold under the trade designation “DiamondPlate Laser Developer” by Western Litho Plate & Supply Co. After 24 hours, each of the plates was removed from the developer and washed thoroughly with tap water. Damaged resist was then wiped off with a sponge, and the optical density (cyan) of each plate was determined. Resist retention was also determined. The results are set forth in Table 2.

TABLE 2

| | Optical Density | Resist Retention |
|---|---|---|
| Test Plates | (Cyan)-(1) | %-(2) |
| 1 | 1.41 | 84% |
| 2 | 1.44 | 87% |
| 3 | 1.45 | 88% |
| 4 | 1.46 | 89% |
| 5 | 1.42 | 85% |
| 6 | 1.39 | 82% |
| 7 | 0.89 | 29% |

Optical Density of Background (No Image Area)-(3): 0.62
Optical Density of Original Solid Image-(4): 1.51
Resiste Retention % was calculated by the following equation.
(2) = {(1) − (3)}/{(4) − (3)}*100

The test results in Table 2 indicate that the condition of the plates being either wet or dry had no substantial affect on the efficiency of the post-exposure process.

### EXAMPLE 3

Five additional 4″×4″ test plates bearing a 1.5″×1.5″ solid image were prepared, exposed and developed substantially in the manner described in Example 1.

The first of these plates was subjected to post-exposure by passing the plate on a conveyor through a post-exposure unit comprising an apparatus obtained from American Ultraviolet Company which contained one medium pressure mercury vapor lamp (360 nm; 38″ in length; 125 watts/in) with cold mirror and IR plate. Dimensions of the conveyor were width 40″, length 30″. The distance from the lamp to conveyor supporting the plate was 4.5″. Speed of the conveyor through the post-exposure unit was 6 ft/min.

The second plate was subjected to post-exposure by passing the plate on a conveyor through a post-exposure unit similar to apparatus 3 containing six 50-watt low vapor Hg lamps sold under the trade designation “Ster-L-Ray G48T6L” by Atlantic Ultraviolet Company. Dimensions of the field of exposure in the exposure unit were width 52″, length 18″. The plate was passed through the post-exposure unit at a speed of 2 ft/min.

A third plate was processed in the same manner as the second plate except that it was passed through the post-exposure unit at a speed of 4 ft/min.

The fourth plate was subjected to post-exposure by placing it under a 6000 watt metal halide lamp sold under the trade designation FT40APR by nuArc Company. Electromagnetic energy impinged on this plate during post exposure was 300 mj/cm².

The fifth plate was not subjected to post-exposure.

All five plates were immersed for five minutes in a liquid developer sold under the trade designation “Polychem XS-790” by U.S. Polychemical Corp. After the samples were removed from the developer they were washed thoroughly with tap water and then wiped with a sponge for removal of damaged resist. Optical density (cyan) of the plates was then checked using a Gretag D-194 densitometer. Results of the tests of this example are set forth in Table 3.

TABLE 3

| | Optical Density | Resist Retention |
|---|---|---|
| Test Plates | (Cyan)-(1) | %-(2) |
| 1 | 1.48 | 92% |
| 2 | 1.45 | 89% |
| 3 | 1.45 | 89% |
| 4 | 1.40 | 84% |
| 5 | 0.79 | 19% |

Optical Density of Background (No Image Area)-(3): 0.61
Optical Density of Original Solid Image-(4): 1.55
Resist Retention % was calculated by the following equation.
(2) = {(1) − (3)}/{(4) − (3) }*100

Table 3 shows that plates 2 and 3 subjected to post-exposure using 254 UV light at low-energy levels are expected to have run lengths which compare very favorably to plates subjected to radiation at higher wavelengths and substantially higher energies.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the invention are achieved and other advantageous results attained.

As various changes could be made in the above methods and constructions without departing from the scope of the invention, it is intended that all matter contained in the above description and shown in the accompanying drawings shall be interpreted as illustrative and not in a limiting sense.

What is claimed is:

1. A process for the preparation of a lithographic printing plate comprising:
exposing select regions of a light sensitive coating of a sensitized negative-working lithographic plate to an electromagnetic beam in a pattern determined by controlling the locus of impingement of said beam on said coating independently of any barrier to said beam, thereby establishing an image in said coating defined by said select regions, said sensitized lithographic plate comprising a support and said light sensitive coating over said support, said light sensitive coating comprising a light sensitive material comprising an ethylenically unsaturated compound and a photosensitive free radical initiator effective for initiating addition polymerization and/or cross-linking reactions;
developing said image by removal of said light sensitive material from the non-exposed regions of said coating;
further exposing said image to electromagnetic radiation comprising a wavelength not greater than about 300 nanometers to promote further addition polymerization and/or cross-linking reactions effective to strengthen said image and increase its press life in a lithographic printing application.

2. A process as set forth in claim 1 wherein said further exposure is to electromagnetic energy comprising a principal wavelength between 200 and about 300 nanometers.

3. A process as set forth in claim 2 wherein said further exposure is to electromagnetic energy comprising a wavelength between about 240 and about 270 nanometers.

4. A process as set forth in claim 1 wherein, during said further exposure, said image is exposed to electromagnetic energy generated by a source which consumes no more than 0.3 kW in generation of said electromagnetic energy.

5. A system for preparing a lithographic printing plate, said plate comprising a support having a light sensitive coating thereon comprising a light sensitive material, said light sensitive material comprising an ethylenically unsaturated compound and a photosensitive free radical initiator effective for initiating addition polymerization and/or cross-linking reactions, said system comprising:
plate exposure apparatus for exposing select regions of said light sensitive coating of said plate to an electromagnetic beam in a pattern determined by controlling the locus of impingement of said beam on said coating thereby establishing an image in said coating defined by said select regions;
plate developing apparatus for developing said image by removal of said light sensitive material from the non-exposed regions of said coating; and
image exposure apparatus for exposing said image to electromagnetic radiation at a wavelength not greater than 300 nm.

6. A system as set forth in claim 5 wherein said image exposure apparatus is operable to expose said image to electromagnetic energy comprising a principal wavelength between 200 and about 300 nanometers.

7. A system as set forth in claim 6 wherein said image exposure apparatus is operable to expose said image to electromagnetic energy comprising a wavelength between about 240 and about 270 nanometers.

8. A system as set forth in claim 5 wherein said image exposure apparatus comprises a electromagnetic energy source which consumes no more than 0.3 kw in generating said electromagnetic energy.

9. A process for the preparation of a lithographic printing plate comprising:
exposing select regions of a light sensitive coating of a sensitized negative-working lithographic plate to an electromagnetic beam in a pattern determined by controlling the locus of impingement of said beam on said coating independently of any barrier to said beam, thereby establishing an image in said coating defined by said select regions, said sensitized lithographic plate comprising a support and said light sensitive coating over said support, said light sensitive coating comprising a light sensitive material comprising an ethylenically unsaturated compound and a photosensitive free radical initiator effective for initiating addition polymerization and/or cross-linking reactions;
developing said image by removal of said light sensitive material from the non-exposed regions of said coating;
further exposing said image to ultraviolet electromagnetic radiation effective: (i) to promote further addition polymerization and/or cross-linking reactions that strengthen said image and increase its press life in a lithographic printing application; and (ii) to produce such cross-linking and image strengthening without consumption of more than 0.3 kW in generation of the radiation during said further exposure.
